(19) United States
(12) Patent Application Publication
(10) Pub. No.: US 2015/0049443 A1
(43) Pub. Date: Feb. 19, 2015

(54) CHIP ARRANGEMENT

(71) Applicant: Infineon Technologies AG, Neubiberg (DE)

(72) Inventor: Georg Meyer-Berg, Muenchen (DE)

(73) Assignee: Infineon Technologies AG, Neubiberg (DE)

(21) Appl. No.: 13/965,246

(22) Filed: Aug. 13, 2013

(51) Int. Cl. H05K 1/18

(52) U.S. Cl. CPC H05K 1/189; H05K 2201/05; H05K 2201/10954
USPC 361/749

(57) ABSTRACT

According to various embodiments, a chip arrangement may be provided, the chip arrangement may include: a first carrier; at least one chip arranged over the first carrier; a flexible structure including a wiring layer structure; and a contact structure arranged between the first carrier and the wiring layer structure, wherein the at least one chip is electrically coupled to the first carrier via the wiring layer structure and the contact structure.

### TECHNICAL FIELD

Various embodiments relate generally to a chip arrangement.

### BACKGROUND

In general, a chip may be mounted on a board, e.g. on a printed circuit board or on any other suitable type of electronic board, such that the chip can be operated in a desired way. Therefore, the chip may be electrically connected with the board, e.g. the chip may include for example chip contacts and the board may include board contacts, wherein the chip contacts of the chip may be electrically conductively coupled to the board contacts of the board. However, since the density of electronic components on a board may rapidly increase due to the fast development of semiconductor technology and/or due to decreasing the feature size of electronic structures, there may be various aspects to be considered in the design of a board and a corresponding mounting technology for one or more chips, e.g. space efficiency, cost efficiency, durability, electronic properties, and the like.

### SUMMARY

According to various embodiments, a chip arrangement may be provided, the chip arrangement may include: a first carrier; at least one chip arranged over the first carrier; a flexible structure including a wiring layer structure; and a contact structure arranged between the first carrier and the wiring layer structure, wherein the at least one chip is electrically coupled to the first carrier via the wiring layer structure and the contact structure.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a chip arrangement in a side view or cross sectional view, according to various embodiments;

FIG. 2 shows a chip arrangement in a side view or cross sectional view, according to various embodiments;

FIGS. 3A and 3B show respectively a detailed view of a chip arrangement at different temperatures, according to various embodiments;

FIG. 4A shows a chip arrangement in a side view or cross sectional view, according to various embodiments;

FIG. 4B shows a top view of a flexible structure including a wiring layer structure included in a chip arrangement, according to various embodiments;

FIGS. 5A and 5B show respectively a chip arrangement in a side view or cross sectional view, according to various embodiments;

FIG. 6 shows a side view or cross sectional view of a chip arrangement including a plurality of chips being arranged on a carrier, according to various embodiments;

FIG. 7 shows a side view or cross sectional view of a chip arrangement including a plurality of chips being arranged on a carrier, according to various embodiments;

FIG. 8 shows a chip arrangement in a side view or cross sectional view, according to various embodiments;

FIGS. 9A to 9D show respectively a flexible structure in a side view or cross sectional view, according to various embodiments;

FIG. 10 shows a schematic flow diagram of a method for manufacturing a chip arrangement, according to various embodiments; and

FIG. 11 shows a chip or a die mounted on a printed circuit board in a conventional way via a ball grid array and an underfill-layer.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

The term “lateral” used with regards to the “lateral” extension of a structure (or of a carrier), may be used herein to mean an extension along a direction parallel to a surface of a carrier. That means that a surface of a carrier (e.g. a surface of a substrate, a surface of a wafer, or the main processing surface of another type of carrier, e.g. of a printed circuit board) may serve as reference, commonly referred to as the main processing surface. Further, the term “width” used with regards to a “width” of a structure (of a chip, or of a carrier) may be used herein to mean the lateral extension of a structure. Further, the term “height” used with regards to a height of a structure (or of a structure element), may be used herein to mean an extension of a structure along a direction perpendicular to the surface of a carrier (e.g. perpendicular to the main processing surface of a carrier).

In general, various different methods may be available for mounting a chip on a board and for electrically connecting a chip with a board, wherein the specific mounting technology may depend on the field of application and further, at least one of the following aspects may be considered: the costs, the electronic properties, the used materials, the operating temperatures of the chip and/or of the board, the contact density of the chip contacts to be connected to the board, the current to be operated by the chip and/or the board, the heat dissipation from the chip and/or the board, the length of the metal lines connecting the chip with the board, the pitch of the metal lines connecting the chip with the board, and the like. Each of the various different methods being commonly available for mounting a chip on a board, e.g. mounting a chip on a printed circuit board (PCB), may include the use of an adapted mounting structure which may suffer from at least one of the following during operating the chip on the board and/or during the assembly of the chip and the board: a reduced heat dissipation from the chip due to the use of mold material, a limited current transport capability due to small board contacts, a reduced mechanical robustness due to the use of soft and flexible board contacts, a complex contact structure resulting in the need of using special individualized (non-standard) mounting equipment, a large pitch of the metal lines due to a small precession during the assembly (e.g. caused by the complex design), design restrictions to planar surfaces being processed, and/or an insufficient compensation of thermal stress due to the different thermal expansion coefficients of the materials of the board and the chip.

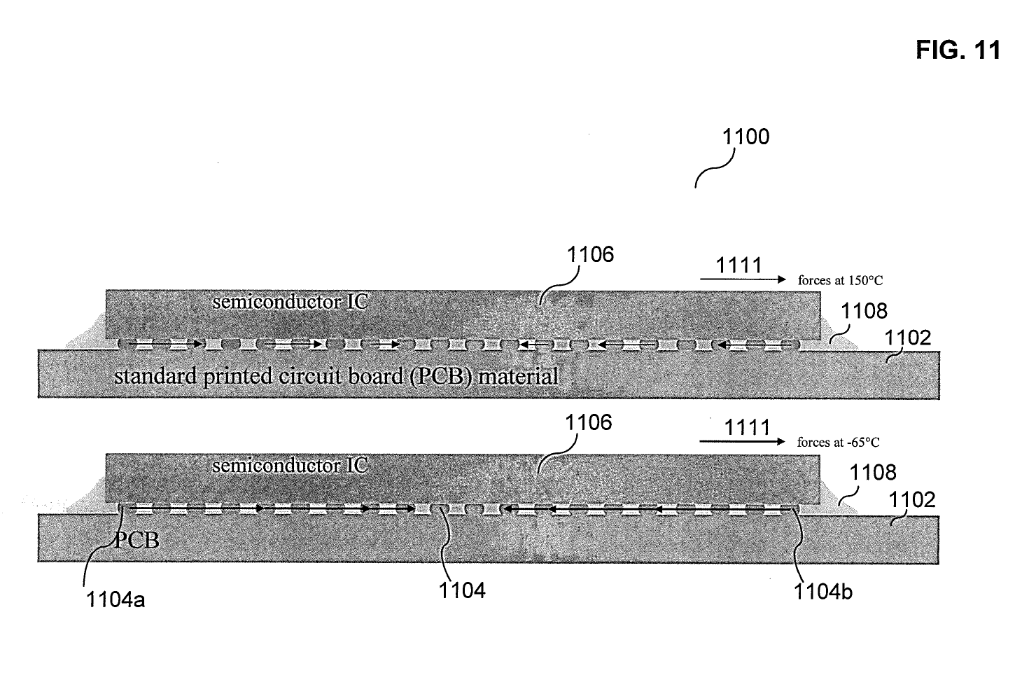

FIG. 11 shows a conventional chip arrangement formed and/or designed via a conventional mounting technology, the conventional chip arrangement 1100 may include: a solder ball grid array 1104 being disposed on a surface of a printed circuit board 1102, directly connecting a chip 1106, e.g. via chip contacts, to a printed circuit board 1102, e.g. via the board contacts, wherein the remaining space 1110 between the chip 1106 and the printed circuit board 1102 may be filled with an underfill material 1108. Since the solder balls of the solder ball grid array 1104 may be rigidly connected with the printed circuit board 1102 and with the chip 1106, or since the printed circuit board 1102 may be rigidly connected to the chip 1106 via the solder ball grid array 1104, thermal induced stress and/or thermally induced strain may be introduced into the chip arrangement 1100. Illustratively, a mechanical load may be introduced into the chip arrangement 1100 due to the different thermal expansion coefficients of the chip and the printed circuit board (or due to the thermal expansion behavior, e.g. the change of the size (e.g. width) of the chip and the change of the size the printed circuit board, due to a change in temperature).

As shown in FIG. 11, a chip 1106 may be soldered to the printed circuit board via the solder ball grid array. The chip may include silicon, e.g. having a lateral thermal expansion coefficient of about 3 ppm/° K, and the printed circuit board may include a board material, e.g. FR-4 (a glass-reinforced epoxy laminate) or BT (a compound based on bismaleimide (B) and triazine resin (T)), the board material may have for example a lateral thermal expansion coefficient of about 13 ppm/° K (for BT) and 16 ppm/° K (for FR-4). In other words, the lateral thermal expansion of the chip 1106 may differ from, e.g. being smaller than, the lateral thermal expansion of the printed circuit board 1102 during a change in temperature such that a direct connection between the chip and the printed circuit board may be prone to errors, e.g. the solder balls may wrenched off due the thermally induced mechanical load. The chip may be solder for example to the printed circuit board at a temperature of about 250° C.; thus, at smaller temperatures than 250° C. stress and/or strain may be introduced into the conventional chip arrangement 1100, as illustrated by the forces 1111 shown in FIG. 11. The forces 1111 may become larger for a decreasing temperature, and the forces 1111 may be larger for the outer solder balls 1104a, 1104b. Therefore, at least the outer solder balls 1104a, 1104b may peel of or may lose the connection to at least one of the chip and the printed circuit board during the assembly; and therefore, the chip may not be contacted properly to the printed circuit board using such a common mounting technology, as described referring to FIG. 11.

As described in the following, according to various embodiments, a chip arrangement may be provided, wherein the chip arrangement may include a chip (or e.g. a die, or an integrated circuit) and a carrier (or e.g. a board, an electronic board, a printed circuit board). According to various embodiments, the chip may be connected directly to the carrier and may be electrically conductively connected to the carrier via a flexible wiring structure. Illustratively, the flexible wiring structure may be configured as an interposer structure being arranged between the chip and the carrier to electrically connect the chip with the carrier (or e.g. to mount the chip on the carrier via the flexible wiring structure and electrically connect the chip to the carrier), wherein, due to the flexibility of the wiring structure, the wiring structure may absorb a mechanical load being subjected to the chip arrangement as a result of the different thermal expansion behavior of the carrier and the chip. Therefore, the electrical connection between the chip and the carrier may not be affected by the different thermal expansion coefficients of the carrier and the chip (or the different thermal expansion behavior of the material included in the carrier (e.g. a laminate (FR-4)) and the material included in the chip (e.g. silicon).

The configuration and/or the design of the chip arrangement, as described herein, may allow the use of standard contacts on the carrier, e.g. SMT (surface mounted technology) contacts (e.g. solder contacts or contact pads) and/or THT (through hole technology) contacts (e.g. metalized through holes), wherein the chip arrangement may withstand large changes in temperature. As a result, the carrier, the chip, and the flexible structure included in the chip arrangement may be designed considering other aspects than the thermally induced load, e.g. the use of a flexible structure as described herein may circumvent the general occurring issue that the involved materials and the mounting design of a chip arrangement has to be designed considering mainly the thermal expansion of the carrier material (e.g. laminates, resin, epoxy, polytetrafluoroethylene (PTFE), and the like) and material of the components to be mounted (e.g. semiconductor materials, glass, ceramic, silicon being for example included in components like dies, chips, and/or integrated circuits) in semiconductor mounting technology or packaging technology.

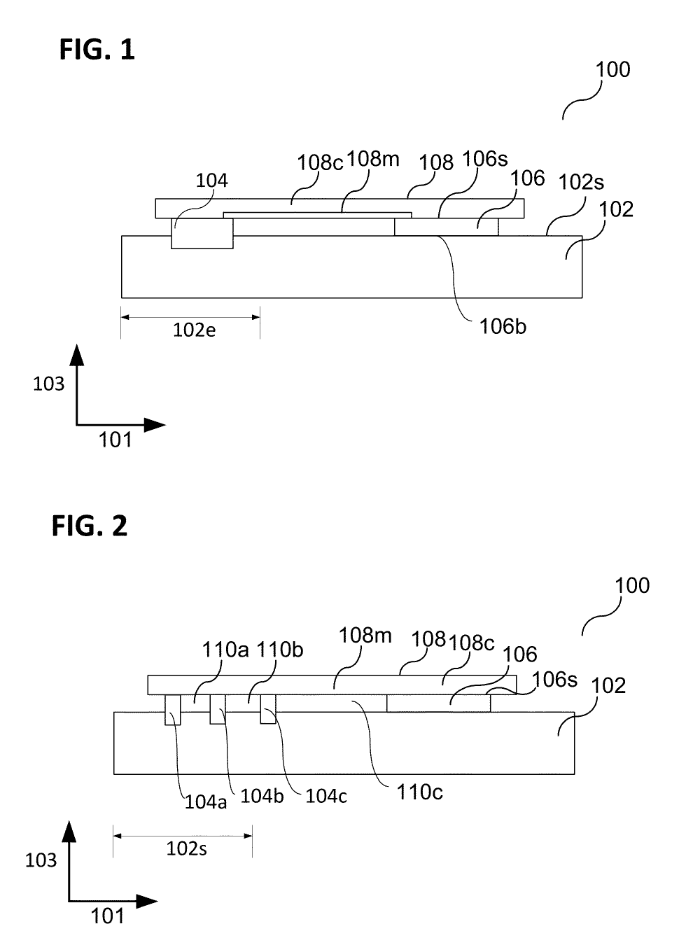

As illustrated in FIG. 1, according to various embodiments, a chip arrangement 100 may be provided, the chip arrangement 100 may include: a first carrier 102; at least one chip 106 arranged over the first carrier 102; a flexible structure 108 including a wiring layer structure 108m; and a contact structure 104 arranged between the first carrier 102 and the wiring layer structure 108m (or between the first carrier 102 and the flexible structure 108), wherein the at least one chip 106 may be electrically conductively coupled to the first carrier 102 via the wiring layer structure 108m and the contact structure 104.

According to various embodiments, the chip arrangement 100 may include the chip 106 being mounted on the carrier 102, wherein the chip 106 may include for example at least one of the following: an integrated circuit (e.g. a digital integrated circuit or an analog integrated circuit), a logic chip, a memory chip, a processor, a microprocessor, a digital signal processor, a sensor, a power management circuit, an operational amplifier, a system-on-a-chip (SOC), an application-specific integrated circuit (ASIC), a field-programmable gate array (FPGA), a microcontroller or any other electronic circuit to be mounted on a carrier, e.g. on a printed circuit board.

According to various embodiments, the first carrier 102 may include at least one of the following: a board, an electronic board, a printed circuit board, a printed wiring board, a printed circuit assembly (PCA), a printed circuit board assembly (PCBA), a ceramic wiring board, a direct copper bonded (DCB) substrate or any other suitable carrier for mounting a chip. Referring to this, according to various embodiments, the first carrier 102 may include at least one material of the following group of materials: a laminate, a copper-clad laminate, copper (e.g. a copper foil), a resin, epoxy, resin impregnated B-stage cloth (Pre-preg), FR-4, BT, a ceramic, and the like.

According to various embodiments, since the chip arrangement 100 may include a flexible structure 108 and a (e.g. flexible) wiring layer structure 108m connecting the chip 106 to the first carrier 102, the carrier material and/or the type of carrier 102 being included in the chip arrangement 100 may be not limited to a specific thermal expansion coefficient (CTE—coefficient of thermal expansion) defined by the thermal expansion coefficient of the chip 106.

According to various embodiments, the contact structure 104, e.g. a part of the contact structure 104 on or near the first carrier 102, may include at least one of the following: one or more contacts, one or more contact pads, one or more SMT (surface mounted technology) contacts, one or more solder contacts or solder contact pads), one or more THT (through hole technology) contacts, one or more metalized through holes.

According to various embodiments, the contact structure 104, e.g. a part of the contact structure 104 on or near the flexible structure 108, may include at least one of the following: one or more solder balls, one or more solder bumps, one or more pins, a solder ball array, a ball grid array (BGA), a pin grid array (PGA) or any other suitable type of contact structure, e.g. including a rigid contact or a plurality of rigid contacts protruding from the flexible structure 108, e.g. a stud bump array.

According to various embodiments, the contact structure 104 may be configured to electrically connect the wiring layer structure 108m (and therefore also the chip 106) to electronic components being arranged at least one of over and in the first carrier 102, e.g. such that the chip 106 may be operated by the first carrier 102. In other words, the first carrier 102 may include one or more electronic components being configured for example to operate the chip 106, the chip 106 being electrically connected to the one or more electronic components via the wiring layer structure 108m of the flexible structure 108 and the contact structure 104.

According to various embodiments, the contact structure 104 may be configured to mechanically support the flexible structure 108 and/or to mechanically support the wiring layer structure 108m. In other words, the flexible structure and/or the wiring layer may be mechanically connected to and/or supported by the contact structure 104.

According to various embodiments, the flexible structure 108 may include a flexible second carrier 108c and a wiring layer structure 108m, the wiring layer structure 108m may be supported by the flexible second carrier 108c. Further, the flexible second carrier 108c may include for example a patterned dielectric structure or a patterned dielectric layer structure 108c and an electrically conductive material structure 108m, wherein the electrically conductive material structure 108m may provide the wiring to electrically conductively connect the chip 106 to the first carrier 102 and/or to electrically conductively connect the chip 106 to the contact structure 104, and/or for example to electrically conductively connect the chip 106 to the first carrier 102 via the contact structure 104.

Further, according to various embodiments, the second carrier 108c of the flexible structure 108 may include at least one carrier of the following group of carriers: a foil, a tape, a resin coated metal foil, a resin coated metal tape, a polymer foil, a polymer tape, a flexible silicon carrier, a resin foil, a resin tape, a dielectric foil, a dielectric tape, an embedding structure, a foil or a tape including a dielectric material, and a metal foil or a metallic tape covered by a dielectric material. According to various embodiments, as described herein, a foil or a tape may have a thickness at least along one spatial direction of smaller than about 1 mm, e.g. smaller than about 500 μm, e.g. smaller than about 200 μm, e.g. smaller than about 100 μm, e.g. smaller than about 50 μm, depending on the material of the foil or the tape. According to various embodiments, the second carrier 108c supporting the wiring layer structure 108m and/or providing the flexible structure 108 may have a shape (e.g. a specific (small) thickness) and/or may include a material (e.g. a specific flexibly material, e.g. a polymer, e.g. a metal) such that the second carrier 108c may be flexible.

According to various embodiments, the term flexible, as used herein, may be related to the mechanical properties of the respective structure (e.g. of the second carrier 108c and/or of the flexible structure 108). Referring to this, a flexible structure may allow repeated deformation along at least one spatial direction for example without damaging the structure, e.g. the flexible structure may react to a mechanical load with an elastic deformation, e.g. permanent elastic deformation. This may allow thousands of mechanical load and unload cycles without considerable plastic deformation. By way of example, this is true for the during cycling required bending radius of the flexible structure. According to various embodiments, the term rigid, as used herein, may be related to the mechanical properties of the respective structure, e.g. a rigid contact or a contact structure. A rigid second carrier may fail at the required bending radius by either causing too high stress at the contacts or by breaking. In general, a relatively easy deformability of the structures should be provided to avoid the occurrence of too large mechanical forces.

Obviously, since all structures may have a specific flexibility and stiffness, depending on the shape and the material of the structures, the term flexibility is used herein for example to described, that a flexible structure may react to a mechanical load induced by a thermal expansion or thermal compression of the first carrier 102, the contact structure 104, the additional contact structure 108s of the flexible structure 108, and/or the chip 104 with a substantial change in shape, size, and/or position, e.g. the flexible structure may react to an applied mechanical load with a substantial displacement. The flexible structure may for example compensate a lateral displacement of the contacts of the contact structure 104 by an elastic deformation, e.g. by bending and/or curling, such that the chip arrangement 100 may withstand a change in temperature without suffering damage.

As shown in FIG. 1, according to various embodiments, the contact structure 104 and the chip 106 may be arranged (disposed) over the same surface 102s of the first carrier 102. Further, the chip 106 may be attached, e.g. soldered or glued, with a first surface 106b to the upper surface 102s of the first carrier 102. Further, the chip 106 may include a chip contact structure being arranged at a second surface 106s of the chip 106, the second surface 106s of the chip 106 being opposite the first surface 106b of the chip 106. According to various embodiments, the chip contact structure may be configured to electrically connect the chip 106 to the wiring layer structure 108m of the flexible structure 108.

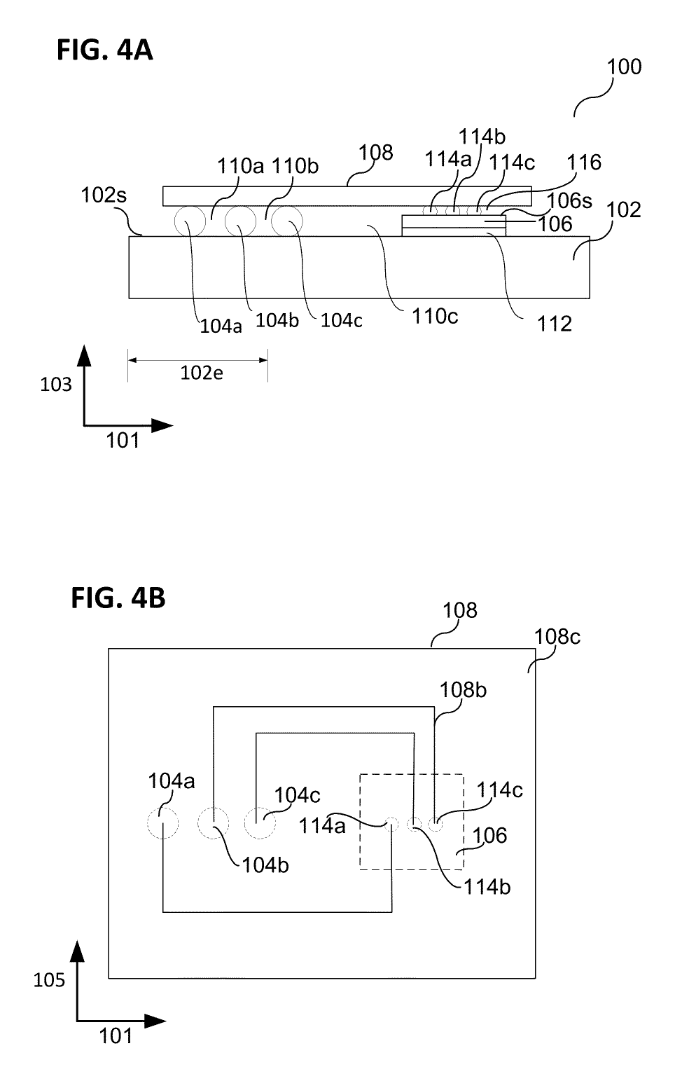

According to various embodiments, the chip contact structure may include at least one of the following: one or more solder balls, one or more solder bumps, one or more pins, one or more contact pads, a solder ball array, a ball grid array (BGA), a pin grid array (PGA), a contact pad array, or any other suitable type of contact structure, e.g. connecting the chip 106 to the flexible structure 108 and/or to the wiring layer structure 108m of the flexible structure 108 (cf. FIG. 4A and FIG. 4B).

According to various embodiments, the flexible structure 108 may be mechanically coupled to the chip 106, e.g. to the second surface 106s of the chip facing away from the first carrier 102. Further, the flexible structure 108 may include a flexible second carrier 108c, the flexible second carrier 108c may be mechanically coupled to the chip 106, e.g. to the second surface 106s of the chip facing away from the first carrier 102. Further, the flexible structure 108 may include a wiring layer structure 108m, the wiring layer structure 108m may be mechanically coupled to the chip 106, e.g. to the second surface 106s of the chip facing away from the first carrier 102. Further, the wiring layer structure 108m may be mechanically coupled to the chip 106, e.g. to the second surface 106s of the chip facing away from the first carrier 102, and electrically conductively coupled to the chip, e.g. to one or more chip contacts arranged on the second surface 106s of the chip facing away from the first carrier 102.

According to various embodiments, the flexible structure 108 may be mechanically coupled to the first carrier 102, e.g. to the upper surface 102s of the first carrier 102 facing in the direction of the chip 106. Further, the flexible structure 108 may include a flexible second carrier 108c, the flexible second carrier 108c may be mechanically coupled to the first carrier 102, e.g. to the upper surface 102s of the first carrier 102 facing in the direction of the chip 106. Further, the flexible structure 108 may include a wiring layer structure 108m, the wiring layer structure 108m may be mechanically coupled to the first carrier 102, e.g. to the upper surface 102s of the first carrier 102 facing in the direction of the chip 106. Further, the wiring layer structure 108m may be mechanically coupled to the first carrier 102, e.g. to the upper surface 102s of the first carrier 102 facing in the direction of the chip 106, and electrically conductively coupled to the first carrier 102, e.g. to one or more carrier contacts or to a contact structure 104 being for example arranged on the upper surface 102s of the first carrier 102 facing in the direction of the chip 106.

According to various embodiments, the flexible structure 108 may be mechanically coupled to the contact structure 104, e.g. to one or more contacts being disposed on the upper surface 102s of the first carrier 102 facing in the direction of the chip 106. Further, the flexible structure 108 may include a flexible second carrier 108c, the flexible second carrier 108c may be mechanically coupled to the contact structure 104, e.g. to one or more contacts being disposed on the upper surface 102s of the first carrier 102 facing in the direction of the chip 106. Further, the flexible structure 108 may include a wiring layer structure 108m, the wiring layer structure 108m may be mechanically coupled to the contact structure 104, e.g. to one or more contacts being disposed on the upper surface 102s of the first carrier 102 facing in the direction of the chip 106. Further, the wiring layer structure 108m may be mechanically coupled to the contact structure 104, e.g. to one or more contacts being disposed on the upper surface 102s of the first carrier 102 facing in the direction of the chip 106, and electrically conductively coupled to the contact structure 104, e.g. to one or more contacts being disposed on the upper surface 102s of the first carrier 102 facing in the direction of the chip 106.

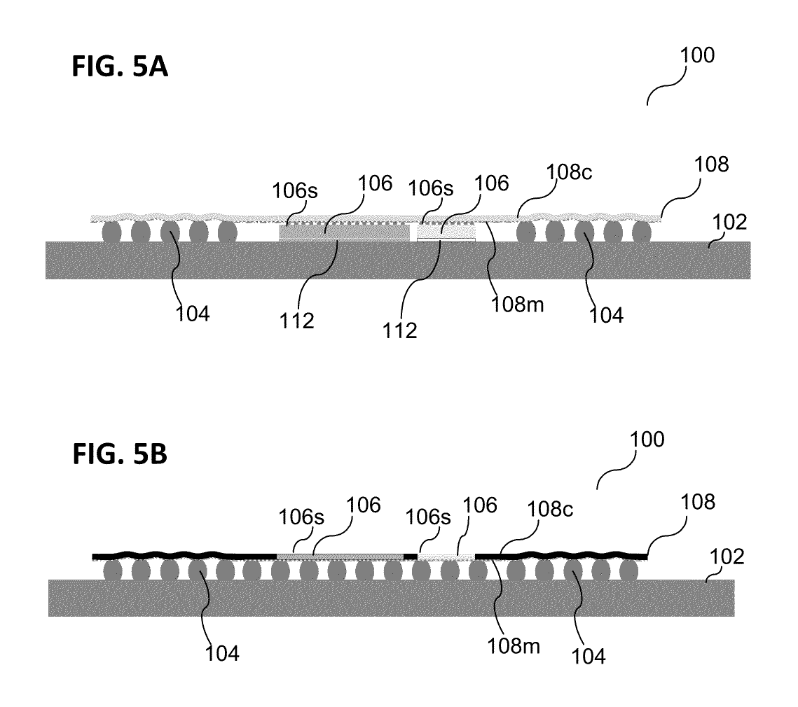

According to various embodiments, the chip 106 may be disposed on the upper surface 102s of the first carrier 102, wherein the contact structure 104 may be disposed on the upper surface 102s of the first carrier 102 laterally next to the chip 106, or the contact structure 104 may be disposed over a first region on the upper surface 102s of the first carrier 102, wherein the chip 106 may be arranged over first region on the surface 102s of the first carrier 102, e.g. over the contact structure 104, as shown for example in FIG. 5B.

According to various embodiments, the chip arrangement 100 may include a plurality of chips, e.g. each chip of the plurality of chips may be disposed over the upper surface 102s of the first carrier 102, as already described referring to the chip 104. In other words, the flexible structure 108 including the wiring layer structure 108m may electrically connect a plurality of chips 104 to a first carrier 102, e.g. to one or more contact pads being arranged on the upper surface 102s of the first carrier 102.

As illustrated in FIG. 2, according to various embodiments, the contact structure 104 may include a plurality of contacts 104a, 104b, 104c. One, more, or all contacts of the plurality of contacts 104a, 104b, 104c may be mechanically coupled to the first carrier 102, and e.g. electrically conductively coupled to a carrier wiring structure arranged in the first carrier 102. According to various embodiments, one, more, or all contacts of the plurality of contacts 104a, 104b, 104c may protrude from the upper surface 102s of the first carrier 102. Thereby, since the contacts of the plurality of contacts 104a, 104b, 104c may be separated from each other, a gap structure (e.g. a plurality of gaps) 110a, 110b may be provided between the contacts of the plurality of contacts 104a, 104b, 104c. Illustratively, at least one gap is provided between two adjacent contacts 104a, 104b of the contact structure 104 and between the electrically isolating structure 106 being disposed over (and/or mechanically connected to) the contacts of the plurality of contacts 104a, 104b, 104c. In other words, the contact structure 104 may include a gap structure 110a, 110b such that one or more gaps may be provided between the contact structure 104 and the flexible structure 108, wherein the flexible structure 108 may be arranged over the contact structure 104. Therefore, according to various embodiments, a free space is provided allowing a displacement of the flexible structure 108 to compensate a mechanical load being subjected to the flexible structure 108 and/or to the wiring layer structure 108m due to a thermally induced expansion 102e of the first carrier 102.

Illustratively, the relative positions of the contacts 104a, 104b, 104c with respect to the chip 104 and/or with respect to the flexible structure 108 may change along a lateral direction 101 due to a thermal expansion 102e of the first carrier 102 caused by a change in temperature, since the contacts 104a, 104b, 104c may be rigidly connected with the first carrier 102.

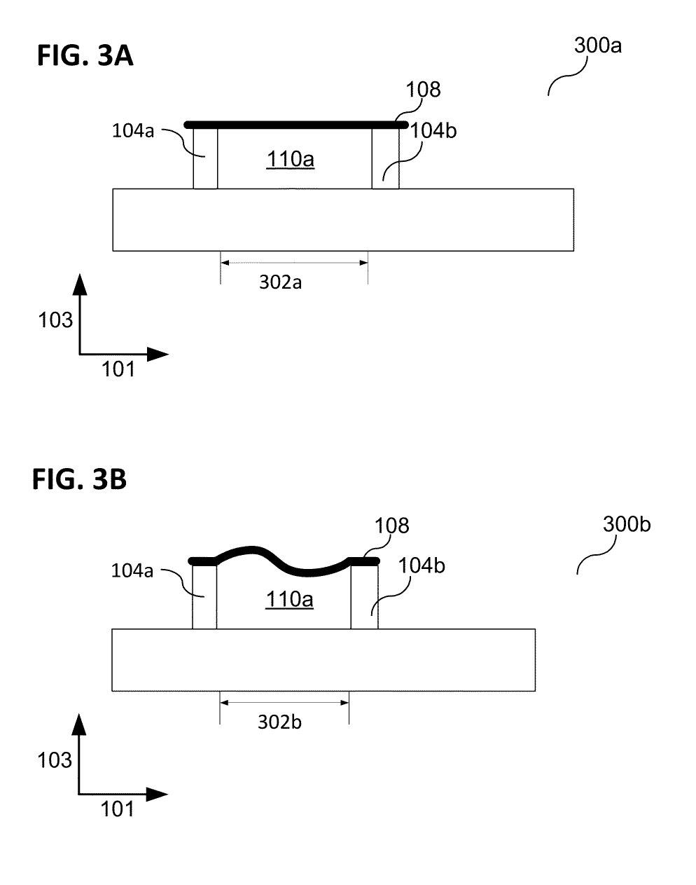

As shown in FIG. 3A and FIG. 3B, the distance between two adjacent contacts 104a, 104b of the contact structure 104 may increase or decrease due to a change in temperature, which may be typical for thermal cycling. FIG. 3A shows the first carrier 102 at a first temperature, e.g. at mounting temperature of about 250° C., since the assembly of the chip arrangement 100 may take place at a temperature in the range from about 100° C. to about 400° C., e.g. at a temperature in the range from about 180° C. to about 350° C., e.g. at a temperature of about 250° C. At this first temperature a first contact 104a and a second contact 104b (e.g. two adjacent contacts of the plurality of contacts included in the contact structure 104) may have a first distance 302a from each other, e.g. along a lateral direction 101 parallel to the upper surface 102s of the first carrier 102. At the first temperature the flexible structure 108 may have a first shape, e.g. as shown in FIG. 3A.

FIG. 3B shows the first carrier 102 at a second temperature, e.g. at room temperature or at a temperature being smaller than the mounting temperature, e.g. at an operating temperature of the chip 106. At this second temperature the first contact 104a and the second contact 104b (e.g. two adjacent contacts of the plurality of contacts included in the contact structure 104) may have a second distance 302b from each other, e.g. along a lateral direction 101 parallel to the upper surface 102s of the first carrier 102, the second distance 302b may be for example smaller than the first distance 302a, since the first carrier 102 may for example shrink due to the temperature change. At the second temperature the flexible structure 108 may have a second shape, e.g. as shown in FIG. 3B.

Illustratively, the shape of the flexible structure 108 may depend on the distance between the first contact 104a and the second contact 104b, since the flexible structure 108 may be fixed to the contacts 104a, 104b. According to various embodiments, since the flexible structure 108 is flexible, as described before, the flexible structure 108 may change its shape in accordance with the change in temperature and related to the change in temperature the change of the relative positions of the one or more contacts of the contact structure 104. The gap 110a between the first contact 104a and the second contact 104b may provide a space such that the flexible structure 108 may change its shape. Referring to this, a part of the flexible structure 108 may be coupled to the contacts of the contact structure 104, wherein another part of the flexible structure 108 may be arranged over the gap between respectively adjacent contacts of the contact structure 104.

According to various embodiments, the flexible structure 108 may be able change its shape, e.g. may be flexible, and therefore the flexible structure 108 may compensate the thermal expansion and/or the thermal shrinking of the first carrier 102 carrier 102, the flexible structure 108 itself, and/or the chip 106 caused by a change in temperature, e.g. heating or cooling. As shown in FIG. 3A and FIG. 3B, at both arbitrarily illustrated temperatures the flexible structure 108 including the wiring layer structure 108m may electrically connect the chip 106 with the first carrier 102. Further, at least a part of the gap 110a or of the gap structure may be free of the flexible structure to provide a space for the flexible structure 108 to change its shape.

According to various embodiments, the chip arrangement 100 as described herein may allow an assembly of the chip 106 and the first carrier 102 (e.g. mounting the 106 chip on the PCB 102) at a first temperature (cf. FIG. 3A) and subsequently cooling the chip to a second temperature (cf. FIG. 3B), wherein the contacts of the contact structure 104 may not lose its electrical connection to the chip 106 and/or to the first carrier 102. Further, according to various embodiments, the flexible structure 108 may not break and/or may not be damaged due to a thermally induced mechanical load, e.g. the load being transferred from the first carrier 102 to the flexible structure 108 via the contact structure 104. Further, the one or more contacts of the contact structure 104 may be rigid (or massive), e.g. solder balls, which may allow an enhanced electrical connection, e.g. an enhanced high-frequency behavior of the contact structure 104 compared to commonly used thin and/or flexible contacts on the PCB.

According to various embodiments, the thermal expansion coefficient of the material of the flexible structure 108 (e.g. along a lateral direction) may be for example adapted to the thermal expansion coefficient of the material of the chip (e.g. silicon having a thermal expansion coefficient of about 3 ppm/° K). The thermal expansion coefficient of the material of the flexible structure 108 may be in the range from about 3 ppm/° K to about 13 ppm/° K, e.g. in the range from about 4 ppm/° K to about 8 ppm/° K, e.g. in the range of about 5 ppm/° K. Therefore, the electrical connection between the chip 106 and the flexible structure 108 (the wiring layer structure 108m) may not be affected by a thermal shrinking of the first carrier 102 after mounting the chip 106 on the first carrier 102 at high temperatures (e.g. about 250° C.).

In contrast, the first carrier 102 may shrink during cooling of the chip arrangement 100 after mounting the chip 106 on the first carrier 102 at high temperatures (e.g. about 250° C.), since the first carrier 102 may include a material having a thermal expansion coefficient of about 15 ppm/° K. Therefore, the flexible structure 108 may be compressed and/or deformed due to the connection to the rigid contacts during cooling of the chip arrangement 100 after the mounting (soldering) of the chip has been carried out.

For example, if the distance 302a between the two adjacent contacts 104a, 104b of the contact structure 104 may be in the range of about 1 mm, during a cooling form a first temperature of 260° C. to −40° C. (e.g. with a CTE difference of about 12 ppm/K between the carrier 102 and the flexible structure 108), the compression of the flexible structure 108 may be in the range of about 3 μm (which is a relative compression of about 3 μm/1 mm), wherein this compression may be for example compensated by the flexibility of the flexible structure 108, as exemplarily shown in FIGS. 3A and 3B.

FIG. 4A exemplarily shows a schematic cross sectional view of the chip arrangement 100. According to various embodiments, the chip 106 may be mounted on (e.g. may be mechanically connected to) the first carrier 102 via a connection layer 112 being disposed between the chip 106 and the first carrier 102. The connection layer 112 may include at least one of a glue or solder. According to various embodiments, the chip may be glued or soldered to the first carrier 102. Thereby, the chip 106 may be attached with a first surface 106b of the chip to the first carrier 102, e.g. by soldering or gluing the first surface 106b of the chip 106 to the upper surface 102s of the first carrier 102.

Further, according to various embodiments, the chip may include a chip contact structure 114 including one or more chip contacts 114a, 114b, 114c, the chip contacts 114a, 114b, 114c being electrically conductively connected to the wiring layer structure 108m of the flexible structure 108 to electrically conductively connect the chip 106 to the wiring layer structure 108m of the flexible structure 108 and therefore, to electrically conductively connect the chip 106 to the first carrier 102 via the one or more contacts 104a, 104b, 104c of the contact structure 104. According to various embodiments, the contacts 104a, 104b, 104c arranged on the upper surface 102s of the first carrier 102 and the chip contacts 114a, 114b, 114c may include at least one of a ball grid array and a pin grid array, as already described.

FIG. 4B exemplarily shows a schematic cross sectional view of the chip arrangement 100 in accordance to the chip arrangement 100 shown in FIG. 4A.

According to various embodiments, the flexible structure 108 and/or the flexible wiring layer structure 108m may be configured as a flexible redistribution structure electrically connecting the at least one chip 106 and the first carrier 102 Therefore, a first part 108a of the wiring layer structure 108m may electrically connect the first chip contact 114a to the first carrier contact 104a, a second part 108b of the wiring layer structure 108m may electrically connect the second chip contact 114b to the second carrier contact 104b, and a third part 108c of the wiring layer structure 108m may electrically connect the third chip contact 114c to the third carrier contact 104c. In general, the flexible structure 108 and the flexible wiring layer structure 108m may electrically conductively connect one or more chip contacts 114 to one or more board contacts 104 (or contacts 104 of the carrier 102). Further, according to various embodiments, the flexible structure 108 and the flexible wiring layer structure 108m may be configured to electrically conductively connect one or more chip contacts being arranged in a first pattern to one or more board contacts 104 being arranged in a second pattern, e.g. the second pattern may differ from the first pattern.

Further, according to various embodiments, the first surface 106b of the chip 106 facing the first carrier 102 may be at least partially thermally coupled to the first carrier 102, e.g. via the connection layer 112, or via the solder layer 112, or via the thermally conducive glue layer 112. This may improve heat dissipation from the chip 106, since the heat may be transferred to the first carrier 102.

Further, according to various embodiments, the flexible structure 108 may additionally serve as heat distribution layer improving the heat dissipation from the chip 106.

Further, according to various embodiments, the chip 106 may include an under bump metallization 116, e.g. including solder bumps to electrically connect the at least one chip with the wiring layer structure. Further, an adhesion improving structure and/or a contamination sheltering innerfill may be disposed between the chip 106 and the flexible structure 108 (not shown).

FIG. 5A illustrates a chip arrangement 100, according to various embodiments, the chip arrangement 100 may include more than one chip 106, e.g. two chips 106. Further, the chip arrangement 100 may include more than two chips, e.g. three, four, five, six, seven, eight, nine, ten, or more than ten chips. According to various embodiments, the chip arrangement 100 may be a multi-chip arrangement including a plurality of chips 106, wherein each chip of the plurality of chips 106 may be electrically conductively connected to the first carrier 102 via the flexible structure 108 including the flexible wiring layer structure 108m, as already described.

As illustrated in FIG. 5A, the flexible structure 108 may have a lateral extension being larger than the lateral extension of the chip 106, e.g. the flexible structure 108 may be configured as a fan-out structure or may include a fan-out structure. As illustrated in FIG. 5A, and already described referring to FIGS. 3A and 3B, the flexible structure 108 may be deformed, e.g. may have a bulged shape, a corrugated shape, a rippled shape, and the like, since the flexible structure 108 having a flat shape may be mounted to the contact structure 104 and or to the first carrier 102 at high temperatures, e.g. at temperatures allowing soldering the wiring layer structure 108m of the flexible structure 108 to the contact structure 104, and the flexible structure 108 may be compressed due to the different thermal expansion coefficients of the first carrier 102 and the flexible structure 108 such that a mechanical load may be subjected to the flexible structure 108 by the contact structure 104 being rigidly connected to the contact structure 104.

According to various embodiments, the contact structure 104 (or the contact structure 104 of the flexible structure 108) may be configured as a metal-ball grid array (M-BGA). Further, the flexible structure 108 may include a foil having a thickness of smaller than about 50 μm. Further, the illustrated configuration of the chip arrangement 100 may allow a high chip fan-out via the wiring layer structure 108m of the flexible structure 108 and the contact structure 104. According to various embodiments, at least a part of the flexible structure 108 may be configured as a heat sink, e.g. including for example a metal. Further, the chips 106 of the chip arrangement 100 may be glued, sintered, or soldered to the first carrier 102 to provide an enhanced thermal coupling to the first carrier 102.

According to various embodiments, due to the short metal lines being utilized in the chip arrangement 100 (e.g. included in the wiring layer structure 108m) and due to the strip line concept the chip arrangement 100 may provide a high electrical and thermal performance.

Further, forming the chip arrangement 100 may include a wafer scale assembly processing. According to various embodiments, the chip arrangement 100 may be reworkable, e.g. since no underfill may be necessary for mounting the chip 106 to the first carrier 102.

Due to the simple processing, the chip arrangement 100 may be cheap and/or may be produced cost-efficiently. Further, the multi-chip mounting compatibility of the chip arrangement 100 may be enhanced. Further, according to various embodiments, the configuration of the chip arrangement 100, as shown herein, may allow the use of a rigid substrate carrier 102. In other words, the first carrier 102 may be a rigid carrier 102.

Further, the chip 106 may have a metallic backside facing towards the first carrier 102, the metallic backside may be configured as an additional heat spreader, e.g. the metallic backside and the chip 106 may be glued, sintered, or soldered to the board 102.

FIG. 5B shows another embodiment, wherein one or more chips 106 may be embedded within the flexible structure 108, and wherein the flexible structure 108 may be mounted together with the emended one or more chips 106 to the contact structure 104 and or to the first carrier 102. Thereby, the contact structure 104 may be arranged below the one or more chips 106 being disposed over the first carrier 102. Thus, referring for example to FIGS. 5A and 5B, being flexible the flexible structure 108 may allow mounting a plurality of chips easily, e.g. a plurality of chips, wherein at least one chip of the plurality of chips may have a different size and/or thickness, than the other chips of the plurality of chips. According to various embodiments, the one or more chips 106 may be thinned after the one or more chips 106 have been embedded in the flexible structure 108, e.g. the one or more chips 106 may be thinned via a grinding process, possibly followed by a silicon plasma etch process, performed after the front-end of line processing has been finished, see e.g. FIG. 5B. The final thickness of the flexible structure 108 (the flexible second carrier 108c) may be for example less than about 100 μm, e.g. less than about 70 μm, e.g. less than about 50 μm, e.g. less than about 35 μm, or e.g. less than about 20 μm.

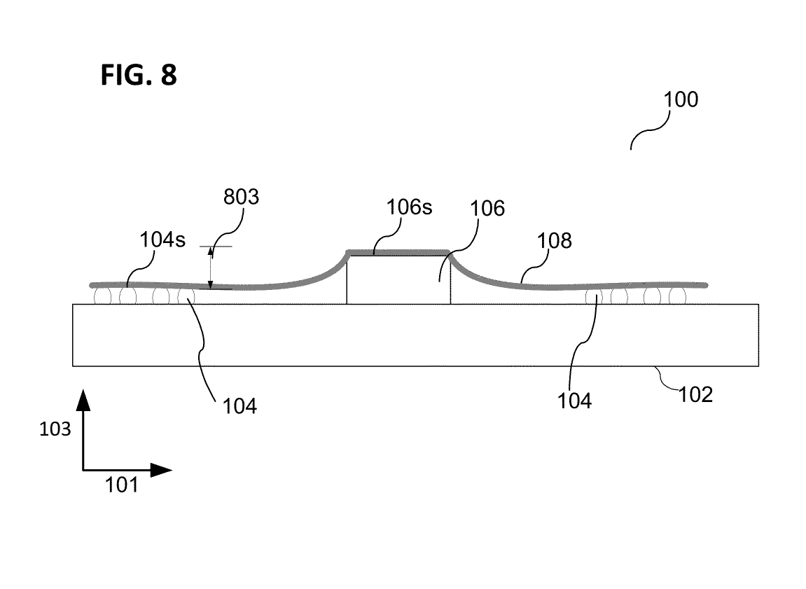

According to various embodiments, the contact structure 104 electrically connecting the first carrier 102 and the flexible structure 108 may include a land grid array (LGA) 104. In various embodiments, the ball pad may be covered with thin solder layer or left blank. An LGA 104 may provide a cost efficient implementation of a contacting structure for the first carrier 102. In the implementation providing an LGA 104, the balls 104 as shown in FIG. 5B, for example, would be replaced by LGA contact structures. The same is possible for replacing the solder balls 104 in FIG. 8.

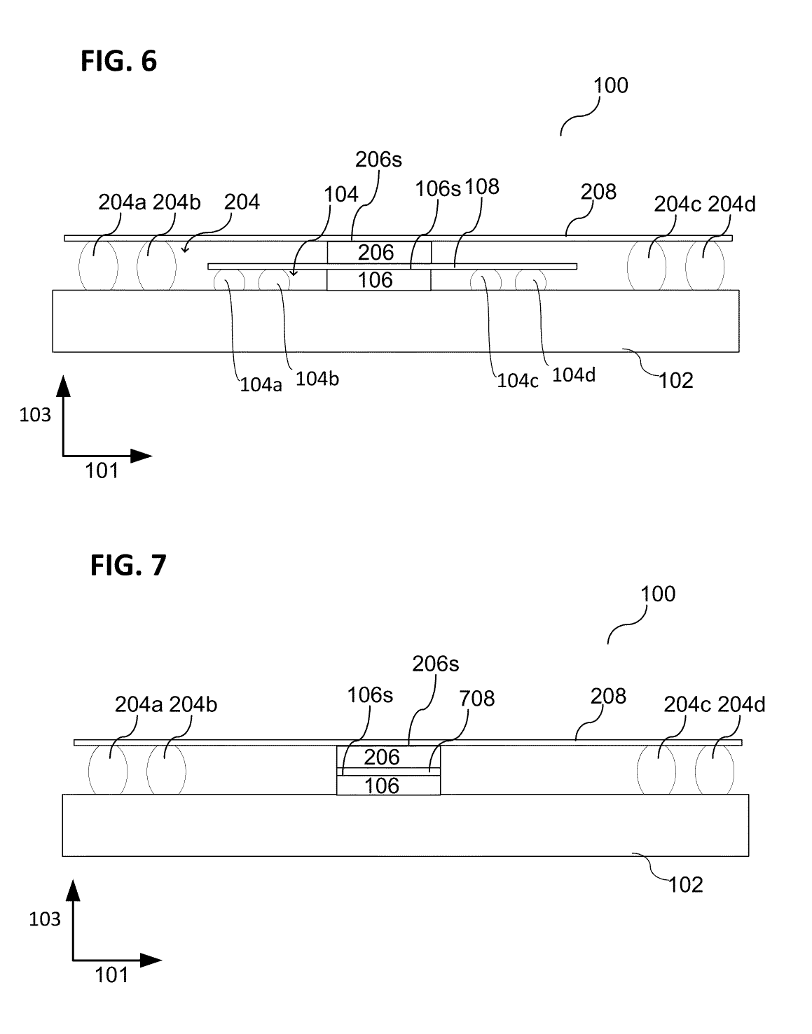

FIG. 6 and FIG. 7 show various embodiments of a chip arrangement 100 including a plurality of chips, exemplarily illustrated for two chips 106, 206. According to various embodiments, as shown in FIG. 6, a first chip 106 may be disposed over the upper surface 102s of the first carrier 102, wherein the first chip 106 may be mechanically coupled to the first carrier 102 via a first flexible structure 108 and wherein the first chip 106 may be electrically coupled to the first carrier 102 via the first flexible structure 108 including a first flexible wiring layer; the flexible structure 108 may electrically conductively connect the first chip 106 to the first carrier 102 via one or more contacts 104a, 104b, 104c, 104d, as already described. Further, a second chip 206 may be disposed over the first chip 106, e.g. over the first flexible structure 108 of the first chip 106. According to various embodiments, the second chip 206 may be electrically connected to the first carrier 102 via a second flexible structure 108 including a second flexible wiring layer, the flexible structure 108 may electrically conductively connect the second chip 206 to the first carrier 102 via one or more contacts 204a, 204b, 204c, 204d, as already described. As illustrated, the flexible structure 108 including a flexible wiring layer structure may allow an optimal redistribution of the chip contacts of one or more chips such that the one or more chips may be electrically conductively connected to the first carrier 102. Thereby, according to various embodiments, the wiring 108m between the one or more chips and the first carrier 102 may be configured to have an optimal length, e.g. providing the shortest realizable connection. The chips 106, 206 may differ from each other in size and thickness. The first chip 106 and/or the second chip 206 may carry through silicon via contacts. Further, the first chip 106 may be connected directly to the carrier via through silicon via contacts. The second chip 206 may be connected directly to the carrier and/or to the first chip 106 through the flexible structure 108 via through silicon via contacts, e.g. without using the contact structures 104, 204. In this case, the contact structures 104, 204 may serve for external IO (input/output) as well as better power supply of the chips 106, 206.

Referring to FIG. 7, an interposer layer 708 may be arranged between the first chip 106 and the second chip 206, the interposer layer 708 may be configured to electrically connect the first chip 106 and the second chip 206, such that the first chip 106 may be electrically connected to the flexible structure 208 being disposed over the second chip 206. The first chip 106 and/or the second chip 206 may be equipped with through silicon via contacts. According to various embodiments, the interposer layer 708 may be configured in a similar way as described herein for the flexible structure 108, e.g. the interposer layer 708 may include a wiring structure. Referring to FIG. 7, the interposer layer 708 may as well be omitted, or being an integral part of the first chip 106 and/or the second chip 206.

As illustrated in FIG. 8, the flexible structure 108 may be configured to compensate a vertical offset 803 between the second surface 106s of the chip 106 and the upper surface 104s of the one or more contacts included in the contact structure 104. In other words, due to the flexibility of the flexible structure 108, the flexible structure 108 may have changed its shape in accordance with the underlying structures (e.g. the chip 106 and the contact structure 104). Further, according to various embodiments, the flexible structure 108 may at least partially surround the chip 106, or may at least partially surround the plurality of chips. Further the flexible structure 108 may be capable to compensate for different vertical offsets 803 at different height levels of 102 and/or its components (not shown here). Further, this may allow simultaneously mounting chips with different thicknesses. The vertical offset compensation described referring to FIG. 8 may be used as well in other embodiments, as described herein.

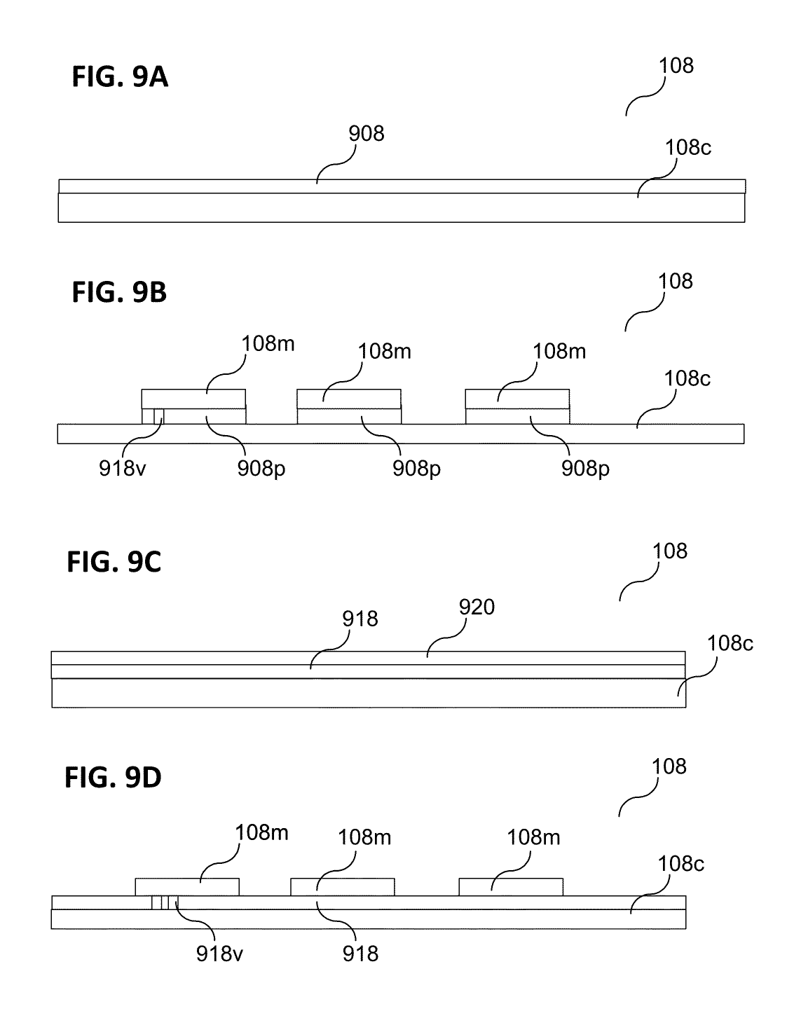

FIG. 9A to FIG. 9D show respectively a detailed view of a flexible structure 108, according to various embodiments. The flexible structure 108 may include a flexible wiring layer structure 108m being configured to redistribute the chip contacts (e.g. the Input-Output (10) pads) of a chip such that the chip contacts may be accessible in other positions. In other words, the flexible structure 108 including a flexible wiring layer structure 108m may be configured or may serve as a redistribution layer (RDL). Illustratively, the flexible structure 108 including the flexible wiring layer structure 108m may be a flexible metallization layer or a flexible metallization structure.

According to various embodiments, the flexible structure 108 being configured as redistribution layer may have a lateral extension being larger than the lateral extension of the first chip 106. Further the flexible structure 108 may allow a fan-out or a fan-in of the chip contacts being disposed on the second surface 106s of the chip 106, as described before. According to various embodiments, the flexible structure 208 being configured as redistribution layer may have a lateral extension being larger than the lateral extension of the second chip 206. Further the flexible structure 208 may allow a fan-out or a fan-in of the chip contacts being disposed on the second surface 206s of the second chip 206, as described before.

According to various embodiments, there may be various possibilities to provide and/or to configure a flexible structure 108 including a wiring layer structure 108m, wherein several embodiments are exemplarily described in the following.

According to various embodiments, a wiring layer structure 108m may be disposed on a second carrier 108c; the second carrier 108c may provide the support for the wiring layer structure 108m. According to various embodiments, the wiring layer structure 108m may be formed directly on the second carrier 108c, e.g. by covering the second carrier 108c with an electrically conductive material (of by forming a layer including an electrically conductive material) and by subsequently patterning the electrically conductive material, wherein the patterned electrically conductive material may provide the wiring layer structure 108m on the second carrier 108c. In the case that the wiring layer structure 108m or the electrically conductive material may be formed directly on the second carrier 108c and in case the second carrier 108c is a conductor, the second carrier 108c may include an electrically insulating material such that the wiring layer structure 108m may be not short circuited by the second carrier 108c. Therefore, according to various embodiments, the second carrier 108c may include at least one material of the following group of materials, the group including: an electrically insulating material, a polymer, an organic material, a resin, epoxy, imide, amide, polyimide, or another plastic material. Further the second carrier 108c may include an electrically conductive material, e.g. a metal (copper, aluminum, iron, nickel, and the like), a metal alloy (e.g. steel, an aluminum alloy, a copper alloy, and the like), or a metallic material, e.g. an electrically conductive nitride (e.g. titanium nitride); however, an additional isolating material may be disposed between the electrically conductive second carrier 108c and the wiring layer structure 108m. Referring to this, the second carrier 108c may include a metal tape being coated with an electrically insulating material, e.g. a resin coated copper foil, a dielectric, polyimide, and the like.

According to various embodiments, the wiring layer structure 108m of the flexible structure 108 may be patterned using typical patterning processes used in semiconductor industry, e.g. a front-end-of-line (FEOL) patterning process including for example at least one of the following: a layering process for forming (e.g. depositing or coating) a mask layer or for forming a mask material layer (e.g. via spin coating of a resist), a lithographic process and a developing process for patterning the mask layer, and an etch process for selectively etching the electrically conductive material being formed over the second carrier 108c to provide a patterned electrically conductive material structure over the second carrier 108c, the patterned electrically conductive material structure may be (or may include) the wiring layer structure 108m. Further, instead or in addition to this, semi additive plating may be applied to provide a patterned electrically conductive material structure. In a semi-additive metallization or plating process, a seed layer, e.g. a metal seed layer, may be utilized to build-up a wiring using photoresist and plating. Thereby, the seed layer may be removed afterwards. The metallization process or forming the wiring may be performed by an electroless plating process or an electrolytic plating process.

According to various embodiments, the wiring layer structure 108m may include one or more metal lines, each metal may for example electrically connect a chip contact of the chip to a carrier contact of the first carrier 102 via the contact structure 104. Therefore, according to various embodiments, the number of metal lines being included in the wiring layer structure 108m of the flexible structure 108 may be defined by the number of chip contacts of the one or more chips to be connected to the first carrier 102 and e.g. the number of connections between said chip contacts.

As shown in FIG. 9A and FIG. 9B respectively in a schematic cross sectional view, a flexible structure 108 including a wiring layer structure 108m may be provided by forming a seed layer 908 over the second carrier 108c for a semi-additive plating, the seed layer 908 may be an electrically conductive seed layer, or an electroplating seed layer. Subsequently, a patterned resist layer may be formed over the seed layer, e.g. by using a layering process providing a resist layer (a photo resist), a lithographic process for exposing the resist layer partially, and subsequently developing the exposed resist layer and partially removing the resist layer. Illustratively, the seed layer 908 may be partially exposed and partially covered by the patterned resist layer. Subsequently, an electrochemical plating process may be carried out (e.g. electroless plating or electrolytic plating), wherein the exposed seed layer 908 may represent an electrode for the electrochemical plating such that for example a metal 108m may deposited over the exposed seed layer 908p; the metal 108m may provide the wiring layer structure. Subsequently, the patterned resist layer may be stripped (removed). Finally, the exposed seed layer may be removed via an etch process. This may allow forming wiring structures with a small feature size. According to various embodiments, the second carrier 108c may include an electrically insulating material or at least the upper surface of the first carrier 102 facing the wiring layer structure 108m may be configured to be electrically insulating. Further, the seed layer 918 may be structured or patterned to form vias for connecting lines 918v from the wiring layer structure 108m to the second carrier 108c.

Alternatively, as shown in FIG. 9C and FIG. 9D respectively in a schematic cross sectional view, a flexible structure 108 including a wiring layer structure may be provided by forming a base layer 918 over the second carrier 108c, the base layer 918 may be an electrically insulating layer or may include an electrically insulating material, e.g. an oxide (aluminium oxide), a dielectric, or a polyimide, and forming a wiring layer 920 over the base layer 918, the wiring layer 920 may include an electrically conductive material to provide the wiring layer structure 108m. According to various embodiments, the wiring layer structure 108m may be formed by patterning the wiring layer 920, e.g. by forming a mask layer over the wiring layer 920, subsequently patterning the mask layer, and subsequently selectively removing (etching) the wiring layer 920 or using semi additive plating. Further, the base layer 918 may be structured or patterned to form vias for connecting lines 918v from the wiring layer structure 108m to the second carrier 108c. Referring to this, a metallic second carrier 108c may be used for the flexible structure 108, wherein the metallic carrier may be connected via the through vias 918v in the base layer 918, such that the second carrier 108c may be used for electrical grounding.

Further, according to various embodiments, the wiring layer structure 108m may be provided using a copper-etch process or an aluminum etch process.

According to various embodiments, a patterning process, as described herein, may include removing a selected portion of a surface layer or of a material. After a surface layer may be partially removed, a pattern (or a patterned layer or patterned surface layer) may remain over the underlying structure (e.g. a pattern may remain on a carrier). Since a plurality of processes may be involved in a patterning process, according to various embodiments, there may be various possibilities to perform a patterning process, wherein aspects may be: selecting at least one portion of a surface layer (or of a surface material) which shall be removed, e.g. using at least one lithographic process; and removing the selected portions of a surface layer, e.g. using at least one etch process. Further, a printing process may be applied. Further, a semi-additive plating process may be applied, as already described.

According to various embodiments, forming a layer (e.g. depositing a layer, depositing a material, and/or applying a layering process) as described herein may also include forming a layer stack including various sub-layers, wherein different sub-layers may include different materials respectively. In other words, various different sub-layers may be included in a layer, or various different regions may be included in a deposited layer and/or in a deposited material. According to various embodiments, a layering process may include a chemical vapor deposition process (CVD process) and/or a physical vapor deposition process (PVD process). Further, according to various embodiments, a process which may be applied to generate a thin layer of a metal may be plating, e.g. electroplating or electroless plating.

According to various embodiments, providing a flexible structure 108 including a wiring layer structure 108m may include at least one layering process and/or at least one patterning process. According to various embodiments, providing a flexible structure 108 including a wiring layer structure may include depositing a layer of a dielectric material (e.g. a low-k dielectric material, e.g. a polymer, polyimide, undoped silicate glass, and the like), forming contact holes at the desired locations (e.g. using a patterning process or laser drilling) and filling the contact holes with at least one electrically conductive material (e.g. at least one of a metal (e.g. aluminium, copper, iron, tungsten, titanium, molybdenum, gold, and the like), a metallic material (e.g. titanium nitride, platinum silicide, titanium silicide, tungsten silicide, molybdenum silicide, and the like), electrically conductive silicon (e.g. electrically conductive polysilicon), and a metal alloy (e.g. aluminium-silicon alloys, aluminium-copper alloys, aluminium-silicon-copper alloys, nickel alloys, e.g. nichrome, titanium-tungsten alloys, copper alloys, iron alloys, and the like)) using a layering process. Further, according to various embodiments, providing the flexible structure 108 including a wiring layer structure 108m may include forming additional layers for example as a diffusion bather (e.g. including at least one of molybdenum, platinum silicide, titanium silicide, tungsten silicide, molybdenum silicide, borides, and the like), or as adhesion promoter (e.g. including at least one of platinum silicide, titanium silicide, tungsten silicide, molybdenum silicide, and the like). According to various embodiments, providing the flexible structure 108 including a wiring layer structure may include performing a lift-off process after having deposited an electrically conductive material over a patterned soft mask, wherein the patterned soft mask may be removed and thereby the electrically conductive material deposited over the soft mask may be partially removed as well.

According to various embodiments, the second carrier 108c of the flexible structure 108 may have a thickness (e.g. an extension along the direction 103 as shown in the figures) in the range from about 1 μm to about 200 μm, e.g. in the range from about 5 μm to about 100 μm, e.g. in the range from about 5 μm to about 50 μm. Referring to this, the second carrier 108c of the flexible structure 108 may include a foil or a tape (e.g. having a thickness smaller than about 200 μm), and therefore, the second carrier 108c of the flexible structure 108 may be a flexible carrier (or a partially flexible carrier along at least one spatial direction) According to various embodiments, the second carrier 108c of the flexible structure 108 may include at least one of the following: a foil, a tape, a metal foil, a resin coated metal foil, a metal tape, a resin coated metal tape, a polymer foil, a polymer tape, a flexible silicon carrier, a resin foil, a resin tape, a dielectric foil, a dielectric tape, and a foil or tape including a dielectric material, or a foil including plastic material (e.g. a polymer, or an organic material). Further, the second carrier 108c of the flexible structure 108 may include an embedding material (as for example shown in FIG. 5B) or an integrated circuit, e.g. the chip itself.

According to various embodiments, the wiring layer structure 108m of the flexible structure 108 may have a thickness (e.g. an extension along the direction 103 as shown in the figures) in the range from about 0.5 μm to about 200 μm, e.g. in the range from about 1 μm to about 100 μm, e.g. in the range from about 5 μm to about 25 μm. Referring to this, the wiring layer structure 108m of the flexible structure 108 may include at least one of the following: a patterned metal foil, a patterned metal tape, one or more metal lines. Further, the wiring layer structure 108m of the flexible structure 108 may be configured as multi-level wiring layer structure including one or more vias and/or through holes. According to various embodiments, the wiring layer structure 108m may include at least one of the following materials: a metal (e.g. aluminium, copper, tungsten, titanium, molybdenum, gold, and the like), a metallic material (e.g. titanium nitride, platinum silicide, titanium silicide, tungsten silicide, molybdenum silicide, and the like), electrically conductive silicon (e.g. electrically conductive polysilicon), and a metal alloy (e.g. aluminium-silicon alloys, aluminium-copper alloys, aluminium-silicon-copper alloys, nichrome, titanium-tungsten alloys, and the like). Referring to this, the wiring layer structure 108m (e.g. having a thickness smaller than about 200 μm) may be a flexible wiring layer structure 108m (or a partially flexible wiring layer structure 108m along at least one spatial direction).

According to various embodiments, since the flexible structure 108 may include a second carrier 108c and a wiring layer structure 108m being both configured to be flexible, as described before, the flexible structure 108 may be also flexible. As described herein, the mechanical properties of the flexible structure 108 may be defined by the materials included in the flexible structure 108 and by the thickness of the flexible structure 108 (or for example by the thickness of the material layers included in the flexible layer structure 108). In various embodiments, the flexible structure 108 may include or be formed of a plurality of layers (of the same or different materials), which may also be referred to as a multilayer structure.

According to various embodiments, the flexible structure 108 may include a plurality of metal lines, wherein the distance between respectively adjacent metal lines may be in the range from about 4 μm to about 1000 μm, e.g. in the range from about 4 μm to about 250 μm, e.g. in the range from about 10 μm to about 100 μm, e.g. in the range from about 10 μm to about 30 μm e.g. in the range of about 20 μm.

According to various embodiments, the width or the lateral extension (e.g. along the direction 101 as shown in the figures) of the flexible structure 108 and/or the wiring layer structure 108m may be in the range from about a few millimeters to about several centimeters or several tens of centimeters, e.g. in the range from about 1 mm to about 50 mm, e.g. in the range from about 1 mm to about 40 mm, e.g. in the range of about 30 mm.

According to various embodiments, the wiring layer structure 108m may be processed on wafer level. Further, the wiring layer structure 108m may be connected to the IO-contacts of the one or more chips on wafer level. In other words, the wiring layer structure 108m of the flexible structure 108 may be a part of the metallization structure of the one or more chips 106. Alternatively, according to various embodiments, the one or more chips 106 may be connected (electrically and/or mechanically) to the wiring layer structure 108m of the flexible structure 108 via solder balls or stud bumps. According to various embodiments, the flexible structure 108 may be a resinated copper foil. Further, the flexible structure 108 including the wiring layer structure 108m may be a patterned resinated copper foil, wherein the copper may be partially removed to provide the wiring layer structure 108m; the wiring layer structure 108m may include for example a plurality of metal lines being electrically separated from each other and/or electrically separated from the second carrier 108c.

As shown in FIG. 9C and FIG. 9D, a resinated copper foil (including a copper layer 920 and a dielectric layer 918) may be disposed over the second carrier 108c (the second carrier 108c, e.g. including an iron/nickel compound, may be a metal foil having for example a thickness of about 100 μm), wherein the copper layer 920 of the resinated copper foil may be partially removed (patterned) via an etch process such that the wiring layer structure 108m may be provided. Alternatively, a resinated aluminum foil (including an aluminum layer 920 and a resin layer 918) may be disposed over the second carrier 108c. According to various embodiments, providing the flexible structure 108 including the wiring layer structure 108m may include at least one of copper etch technology and aluminum etch technology.

According to various embodiments, before the flexible structure 108 may be mounted on a first carrier 102 to electrically connect at least one chip 106 to the contact structure 104, the flexible structure 108 may be subjected to a trim and form process. This may prepare the first carrier 102 with topography.

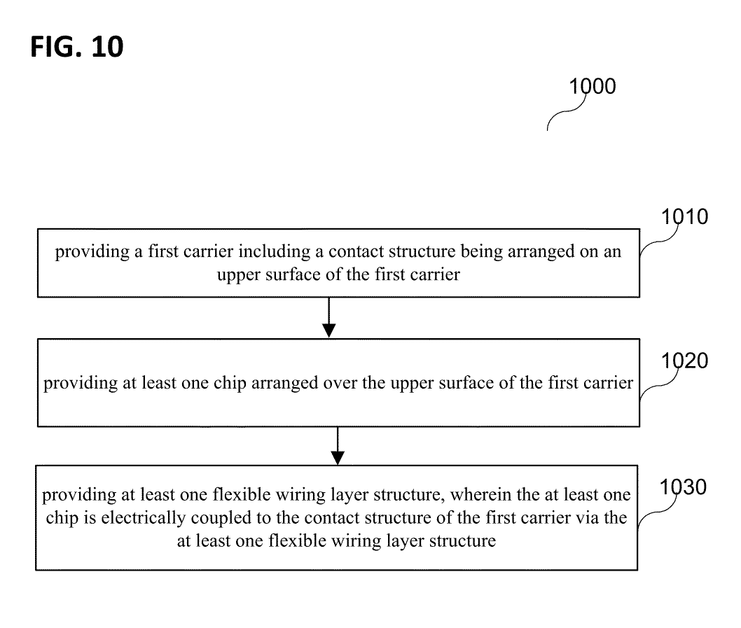

FIG. 10 illustrates schematically a flow diagram of a method for manufacturing a chip arrangement 100, as described herein; the method including; in 1010, providing a first carrier 102 (e.g. a printed circuit board) including a contact structure 104 being arranged on an upper surface 102s of the first carrier 102; in 1020, providing at least one chip 106 (one or more chips) being arranged over the upper surface 102s of the first carrier 102; and, in 1030, providing at least one flexible wiring layer structure 108, wherein the at least one chip 106 may be electrically conductively coupled to the contact structure 104 via the at least one flexible wiring layer structure 108. In various embodiments, balls may be provided at the flexible structure 108. Furthermore, in various embodiments, balls may be omitted and e.g. an LGA contact structure may be provided at the flexible structure 108.

According to various embodiments, the flexible structure 108 (and therefore the wiring layer structure 108m) may be configured (e.g. by adapting the thickness and the materials being used) to withstand a lateral displacement of the contact structure 104, the contact structure 104 may be mechanically coupled to the flexible structure 108, e.g. the flexible structure 108 may be configured to perform a change of its the position and/or its shape to compensate a lateral mechanical load being subjected to, e.g. due to a lateral thermal expansion or a lateral thermal shrinking of the first carrier 102 if a temperature change occurs.

According to various embodiments, the flexible structure 108 (e.g. the flexible second carrier 108c and/or the flexible wiring layer structure 108m) may be configured as a thermo-mechanical buffer between silicon (e.g. a chip) and laminate (e.g. an electronic board (e.g. a PCB)); this may allow mounting a chip one a board without the use of glue or underfill material (e.g. as used in common mounting technologies, cf. FIG. 11) and/or without the use of flexible contacts (e.g. as used in lead frame based packages). In general, a glue or an underfill material may reduce the heat dissipation from the chip or from the plurality of chips during operation, since the chip may be thermally isolated by the glue or the underfill material.

According to various embodiments, the flexible structure 108 may be configured to adapt the layout of the chip contact arrangement to the layout of the board contact arrangement. Further, the flexible structure 108 (e.g. the flexible second carrier 108c and/or the flexible wiring layer structure 108m) may be configured to have a (e.g. lateral) thermal expansion coefficient (CTE) in the range of the (lateral) thermal expansion coefficient of the at least one chip 106. Therefore, the chip contacts may be of low thermally induced strain and/or stress.

According to various embodiments, the flexible structure 108 may be mounted (connected) to the contact structure 104 and to the at least one chip 106 at a temperature which may allow soldering at least one of the chip and the contact structure 104 to the flexible structure 108 (e.g. a temperature in a range from about 100° C. to about 400° C., e.g. from about 180° C. to about 350° C., e.g. of about 250° C.); therefore, the flexible structure 108 may be in a stressless state at a high temperature (compared to the operating temperatures of the chip arrangement 100. During cooling the chip arrangement 100, for example starting from the stressless state at a high temperature to room temperature (or even lower temperatures), the board (the first carrier 102) may shrink (or may contract itself) more than the flexible structure 108 (since the CTE of the board of about 15 ppm/° K may be larger than the CTE of the flexible structure 108 of about 5 ppm/° K, since the CTE of the flexible structure 108 may be adapted to the CTE of the at least one chip 106); thus, due to the rigid contacts of the contact structure 104 the flexible structure 108 may be compressed. For example, the compression of the flexible structure 108 may be in the range of about 3 μm per 1 mm for a temperature change from about 260° C. to about −40° C., as described before. It is to be noted that the CTE difference depends on the materials and the respective structures and materials provided. Thus, the above example is specific and valid for the specific structure as described above. However, these values should not be understood to be limiting and the values may substantially vary in other embodiments.

The configuration of the chip arrangement 100, as described herein, may enable the use of solder balls (rigid contacts) or LGAs; therefore, according to various embodiments, the heat transfer from the flexible structure 108 to the board may be enhanced; the mounting process may be performed as performed usually for common ball grid arrays (e.g. a standard solder process may be used, e.g. with a known optimal thickness of solder material being disposed over the board); due to the mechanical stability of the solder balls and/or the soldered contacts of the contact structure 104 the chip arrangement 100 may be more robust against a mechanical load; and/or due to the massive electrical contacts of the contact structure 104 (e.g. solder balls) the high-frequency properties of the chip arrangement 100 may be enhanced.

Further, the one or more chips 106 of the chip arrangement 100 may not need a flip-chip mounting process, since the electrical contacting may be provided via the wiring layer structure 108m of the flexible structure 108; therefore, the whole surface of the first carrier 102 may be used to provide contacts for connecting to the contact structure 104 (cf. FIG. 5B); and therefore, the chip arrangement 100 and/or the first carrier 102 may have a better and/or e.g. smaller form factor.

Further, according to various embodiments, the configuration of the chip arrangement 100, as described herein, may enable the use of various materials, since the materials included in the first carrier 102 may not be chosen in accordance with the CTE of the chip 106, the first carrier 102 may include for example electrically conductive materials, an insulated metal substrate with copper core and/or aluminum core, electrically semiconducting materials, electrically insulating materials, organic materials, and/or inorganic materials, being suitable for subsequently performed processes for providing the external electrical contacts.

Illustratively, according to various embodiments, thermo-mechanical stress (and/or strain) may be compensated (buffered) by the flexible structure 108 including the wiring layer structure 108m. This may allow a high fan-out (in an enlarged area compared to conventional solder ball arrays) using a solder ball grid array.

According to various embodiments, the flexible structure 108 including the flexible wiring layer structure 108m, e.g. as shown in FIG. 9, may be processed on wafer or panel level or strip level or may be at least partially processed on wafer level, which may allow a small pitch and forming a wiring layer structure 108m with a cost effective high precision.

According to various embodiments, utilizing a rigid contact structure 104, e.g. solder balls, and a flexible structure 108 for electrically connecting one or more chips with an electronic board (a carrier 102) may allow transferring a large amount of heat from the one or more chips to the electronic board. Further, the flexible structure 108 may include a metal structure which may serve as heat sink structure; the metal heat sink structure may include at least one metal surface exposed to the environment and/or may include one or more cooling fins. According to various embodiments, the flexible wiring layer structure 108m of the flexible structure 108 may electrically conductively connect one or more chips to an electronic board and, at the same time, may be configured to spread heat generated by the one or more chips. In this case, the flexible structure 108 may include a low doped copper substrate, e.g. CuFe_{0.1}P.

According to various embodiments, a chip arrangement may include: a first carrier; at least one chip arranged over the first carrier; a flexible structure including a wiring layer structure; and a contact structure arranged between the first carrier and the wiring layer structure, wherein the at least one chip may be electrically coupled to the first carrier via the wiring layer structure and the contact structure.

According to various embodiments, the at least one chip may be additionally electrically coupled to the first carrier directly via the wiring layer structure.

According to various embodiments, the contact structure and the at least one chip may be arranged over the same surface of the first carrier.

According to various embodiments, the at least one chip may include a first surface attached to the first carrier; the at least one chip may include a chip contact structure arranged at a second surface of the at least one chip, the second surface being opposite the first surface; and wherein the chip contact structure may be configured to electrically (e.g. conductively) connect the at least one chip to the wiring layer structure of the flexible structure.

According to various embodiments, the first carrier may be configured as a printed circuit board. Further, the first carrier may include a laminate material and one or more carrier contacts.

According to various embodiments, the contact structure may include a plurality of contacts. According to various embodiments, the contacts of the plurality of contacts may be separated from each other providing a gap structure between the contacts of the plurality of contacts.

According to various embodiments, a contact structure of the flexible structure may include a grid array contact structure.

According to various embodiments, the grid array contact structure may include a land grid array contact structure.

According to various embodiments, the at least one flexible wiring layer structure may be mechanically coupled to the contacts of the plurality of contacts, wherein at least a part of the gap structure may be free of the flexible wiring layer structure.

According to various embodiments, the at least one chip may be arranged between the flexible structure and carrier.

According to various embodiments, the chip contact structure may include one of a ball grid array, a pin grid array, or a stud bump array.

According to various embodiments, the flexible structure may include at least one carrier of the following group of carries: a foil; a tape; a dielectric covered metal foil; a resin coated metal foil; a resin coated metal tape; a polyimide covered metal foil; and a flexible polyimide covered silicon carrier.

According to various embodiments, the flexible structure may include at least one metal foil (one or more metal foils) including at least one of the following: a layer or a layer stack including an iron alloy, a layer or a layer stack including stainless steel, a layer or a layer stack including a low CTE-alloy, a layer or a layer stack including Alloy 42, a layer or a layer stack including copper plated Alloy 42, a layer or a layer stack including Pernifer 36, a layer or a layer stack including a copper based alloy, a layer or a layer stack including CuFe₂P, and a layer or a layer stack including CuAg.

According to various embodiments, the flexible structure may include a material and the flexible structure may be configured (in shape and size) to perform a plastic and/or elastic deformation to absorb a mechanical load, e.g. due to a thermal expansion of the first carrier.

According to various embodiments, the wiring layer structure may be configured as a flexible redistribution structure (e.g. fan-in or fan-out) electrically connecting the at least one chip with the first carrier.

According to various embodiments, at least one surface of the chip facing the first carrier may be at least partially thermally coupled (e.g. glued or soldered) to the first carrier.

According to various embodiments, the flexible structure may include a thermally conductive heat sink structure being thermally coupled to the at least one chip (e.g. thermally conductively coupled).

According to various embodiments, the at least one chip may include an under bump metallization electrically connecting the at least one chip to the wiring layer structure. According to various embodiments, the under bump metallization may be arranged between the least one chip and the flexible structure.

According to various embodiments, the chip arrangement may include bumps coupled to the at least one chip.

According to various embodiments, the flexible structure may include a plurality of layers.

According to various embodiments, a chip arrangement may include: a printed circuit board including a contact structure being arranged on a first surface of the printed circuit board; at least one chip arranged over the first surface of the printed circuit board; and at least one flexible wiring layer structure; wherein the at least one chip may be electrically conductively coupled to the contact structure of the printed circuit board via the at least one flexible wiring layer structure. According to various embodiments, the flexible wiring layer structure may include a second carrier and a wiring structure; the wiring structure may include for example one or more metal lines and/or one or more contacts.

According to various embodiments, the contact structure of the printed circuit board may include a plurality of contacts protruding from the printed circuit board (e.g. from the upper surface of the printed circuit board facing towards the at least one chip), wherein the contacts of the plurality of contacts may be separated from each other providing a gap between respectively adjacent contacts of the plurality of contacts.

According to various embodiments, the at least one flexible wiring layer structure may be mechanically coupled to each contact of the plurality of contacts, and at least a part of the gap between respectively adjacent contacts of the plurality of contacts may be free of the flexible wiring layer structure.

According to various embodiments, the at least one flexible wiring layer structure may be configured as a flexible foil or tape. According to various embodiments, a flexible foil or tape may have a thickness of smaller than about 150 μm, e.g. smaller than about 100 μm, e.g. smaller than about 60 μm.

According to various embodiments, the at least one chip may include a first chip and a second chip; further, the at least one flexible wiring layer structure may include a first flexible wiring layer structure and a second flexible wiring layer structure; wherein the first chip may be arranged over the first surface of the printed circuit board and may be electrically conductively connected to the contact structure of the printed circuit board via the first flexible wiring layer structure, and wherein the second chip may be arranged over the first surface of the printed circuit board and may be electrically conductively connected to the contact structure of the printed circuit board via the second flexible wiring layer structure,

Further, according to various embodiments, the first chip may be arranged over the first surface of the printed circuit board and the first flexible wiring layer structure may be arranged over an upper surface of the first chip facing away from the printed circuit board, wherein the second chip may be arranged over the first flexible wiring layer structure and the second flexible wiring layer structure may be arranged over an upper surface of the second chip facing away from the printed circuit board.

According to various embodiments, the at least one chip may include a plurality of chips; and the chips of the plurality of chips may be stacked above each other forming a chip stack, the chip stack being electrically conductively connected to the printed circuit board via the at least one flexible wiring layer structure.

According to various embodiments, the at least one chip may be embedded into the flexible wiring layer structure.

According to various embodiments, the chip may include at least one surface being at least partially thermally conductively coupled to the first carrier, e.g. via a solder material or a thermally conductive glue.

According to various embodiments, the contact structure arranged between the first carrier and the flexible wiring structure may be regarded as a part of the first carrier or at least a part of the contact structure may be regarded as a part of the first carrier. According to various embodiments, the contact structure arranged between the first carrier and the flexible wiring structure may be regarded as a part of the flexible structure or the flexible wiring structure or at least a part of the contact structure may be regarded as a part of the flexible structure or the flexible wiring structure.

According to various embodiments, the conductive flexible structure may be electrically conductively and/or mechanically connected to at least one contact of the wiring layer structure. According to various embodiments, the flexible structure may include one or more vias, being electrically conductively connected to at least one contact of the contact structure. According to various embodiments, the flexible structure may include one or more vias.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip arrangement, comprising:
a first carrier;
at least one chip arranged over the first carrier;
a flexible structure comprising a wiring layer structure; and
a contact structure arranged between the first carrier and the wiring layer structure,
wherein the at least one chip is electrically coupled to the first carrier via the wiring layer structure and the contact structure.

2. The chip arrangement according to claim 1,
wherein the contact structure and the at least one chip are arranged over the same surface of the first carrier.

3. The chip arrangement according to claim 1,
wherein the at least one chip comprises a first surface being attached to the first carrier;
wherein the at least one chip comprises a chip contact structure arranged at a second surface of the at least one chip, the second surface being opposite the first surface; and
wherein the chip contact structure is configured to electrically connect the at least one chip to the wiring layer structure of the flexible structure.

4. The chip arrangement according to claim 1,
wherein the first carrier is configured as a printed circuit board.

5. The chip arrangement according to claim 1,
wherein the contact structure comprises a grid array contact structure.

6. The chip arrangement according to claim 5,
wherein the grid array contact structure comprises a land grid array contact structure.

7. The chip arrangement according to claim 1,
wherein the flexible structure comprises at least one carrier of the following group of carries, the group comprising:
a foil;
a tape;
a dielectric covered metal foil;
a resin coated metal foil;
a resin coated metal tape;
a polyimide covered metal foil; and
a flexible polyimide covered silicon carrier.

8. The chip arrangement according to claim 1,
wherein the flexible structure comprises at metal foil, the metal foil comprising at least one of the following: a layer or a layer stack comprising an iron alloy, a layer or a layer stack comprising stainless steel, a layer or a layer stack comprising a low CTE-alloy, a layer or a layer stack comprising Alloy 42, a layer or a layer stack comprising copper plated Alloy 42, a layer or a layer stack comprising Pernifer 36, a layer or a layer stack comprising a copper based alloy, a layer or a layer stack comprising CuFe₂P, and a layer or a layer stack comprising CuAg.

9. The chip arrangement according to claim 8,
wherein the conductive flexible structure is connected to at least one contact of the wiring layer structure.

10. The chip arrangement according to claim 1,
wherein the wiring layer structure is configured as a flexible redistribution structure electrically connecting the at least one chip with the first carrier.

11. The chip arrangement according to claim 1,
wherein the chip comprises at least one surface being at least partially thermally conductively coupled to the first carrier.

12. The chip arrangement according to claim 1,
wherein the flexible structure comprises a thermally conductive heat sink structure being thermally conductively coupled to the at least one chip.

13. The chip arrangement according to claim 1,
wherein at least one chip comprises an under bump metallization, the under bump metallization is electrically connecting the at least one chip with the wiring layer structure.

14. The chip arrangement according to claim 1, further comprising:
bumps coupled to the at least one chip.

15. The chip arrangement according to claim 1,
wherein the flexible structure comprises a plurality of layers.

16. A chip arrangement, comprising:
a printed circuit board comprising a contact structure being arranged on a first surface of the printed circuit board;
at least one chip arranged over the first surface of the printed circuit board; and
at least one flexible wiring layer structure;
wherein the at least one chip is electrically coupled to the contact structure of the printed circuit board via the at least one flexible wiring layer structure.

17. The chip arrangement according to claim 16,
wherein the contact structure of the printed circuit board comprises a plurality of contacts protruding from the printed circuit board, wherein the contacts of the plurality of contacts are separated from each other providing a gap between respectively adjacent contacts of the plurality of contacts.

18. The chip arrangement according to claim 17,
wherein the at least one flexible wiring layer structure is mechanically coupled to each contact of the plurality of contacts, and
wherein at least a part of the gap between respectively adjacent contacts of the plurality of contacts is free of the flexible wiring layer structure.

19. The chip arrangement according to claim 16,
wherein the at least one flexible wiring layer structure is configured as a flexible foil or a flexible tape.

20. The chip arrangement according to claim 16,
wherein the at least one chip comprises a first chip and a second chip;
wherein the at least one flexible wiring layer structure comprises a first flexible wiring layer structure and a second flexible wiring layer structure;
wherein the first chip is arranged over the first surface of the printed circuit board and is electrically conductively connected to the contact structure of the printed circuit board via the first flexible wiring layer structure, and
wherein the second chip is arranged over the first surface of the printed circuit board and is electrically conductively connected to the contact structure of the printed circuit board via the second flexible wiring layer structure.

21. The chip arrangement according to claim 20,
wherein the first chip is arranged over the first surface of the printed circuit board and the first flexible wiring layer structure is arranged over an upper surface of the first chip facing away from the printed circuit board, and
wherein the second chip is arranged over the first flexible wiring layer structure and the second flexible wiring layer structure is arranged over an upper surface of the second chip facing away from the printed circuit board.

22. The chip arrangement according to claim 16,
wherein the at least one chip comprises a plurality of chips; and
wherein the chips of the plurality of chips are stacked above each other forming a chip stack, the chip stack being electrically conductively connected to the printed circuit board via the at least one flexible wiring layer structure.

23. The chip arrangement according to claim 16,
wherein the at least one chip is embedded into the flexible wiring layer structure.
